(19) United States
(12) Patent Application Publication
(10) Pub. No.: US 2014/0332182 A1
(43) Pub. Date: Nov. 13, 2014

(54) Heat Sink For Cooling Power Electronics

(71) Applicants: Michael F. Taras, Fayetteville, NY (US); KeonWoo Lee, Manlius, NY (US); Mark J. Perkovich, Liverpool, NY (US); Suresh Duraisamy, Liverpool, NY (US); XuQiang Liao, Manlius, NY (US)

(72) Inventors: Michael F. Taras, Fayetteville, NY (US); KeonWoo Lee, Manlius, NY (US); Mark J. Perkovich, Liverpool, NY (US); Suresh Duraisamy, Liverpool, NY (US); XuQiang Liao, Manlius, NY (US)

(73) Assignee: Carrier Corporation, Farmington, CT (US)

(21) Appl. No.: 14/117,386

(22) PCT Filed: Apr. 12, 2012
(86) PCT No.: PCT/US12/33184

§ 371 Date: Nov. 13, 2013

Related U.S. Application Data
(60) Provisional application No. 61/487,068, filed on May 17, 2011.

(51) Int. Cl. H05K 7/20

(52) U.S. Cl. CPC H05K 7/20145; H05K 7/20409
USPC 165/80.3

(57) ABSTRACT

A heat sink device for cooling a power electronics module includes a base platform having a first surface and a second surface on opposite sides of the base platform, a plurality of upright members extending outwardly from the first surface of the base platform and defining a cavity wherein the power electronics module is disposed in conductive heat exchange relationship with the first surface of the base platform, and a plurality of heat transfer fins extending outwardly from the second surface of the base platform and defining a plurality of cooling air flow channels.

### CROSS-REFERENCE TO RELATED APPLICATION

Reference is made to and this application claims priority from and the benefit of U.S. Provisional Application Ser. No. 61/487,068, filed May 17, 2011, and entitled HEAT SINK FOR COOLING POWER ELECTRONICS, which application is incorporated herein in its entirety by reference.

### BACKGROUND OF THE INVENTION

This invention relates generally to cooling electronics components, for example isolated-gate bipolar transistors (IGBT), semiconductor devices, capacitors and other components of an electronic device, such as, for example a power electronics module of a variable speed drive.

Power electronic devices are commonly used for controlling and/or manipulating the characteristics, for example the frequency and/or the voltage, of the electric power being supplied to a variety of electrically powered devices. For example, variable speed drives are commonly used in connection with variable speed motors for controlling the speed of the motor. Variable speed motors are used in connection with compressors, water pumps, fans and other devices. For example, refrigerant vapor compressors, such as, but not limited to, scroll compressors, reciprocating compressors and screw compressors, to enable driving the compression mechanism of the compressor at various operating speeds. As the operating speed of the compression mechanism is decreased, the output capacity of the compressor is decreased, and conversely as the operating speed of the compressor is increased, the output capacity of the compressor is increased. The variable speed drive is operative to vary the frequency of the electric power supplied to drive motor of the compressor, thereby varying the operating speed of the motor, and consequently the operating speed and output capacity of the compressor.

In operation, adequate cooling the power electronics devices, such as but not limited to variable speed drives, must be ensured by removing heat generated by the power electronics so as to maintain the reliability and the functionally of the power electronics devices.

### SUMMARY OF THE INVENTION

In an aspect, a heat sink device is provided that is useful for cooling a power electronics module at a temperature below a specified operating threshold temperature.

In an aspect, a heat sink device is provided that is useful for cooling the power electronics of a variable speed drive housed in a sealed enclosure through which a flow of cooling air is directed over and across the heat sink device.

A heat sink device for cooling a power electronics module includes a base platform having a first surface and a second surface on opposite sides of the base platform, a plurality of upright members extending outwardly from the first surface of the base platform and defining a cavity wherein the power electronics module is disposed in conductive heat exchange relationship with the first surface of the base platform, and a plurality of heat transfer fins extending outwardly from the second surface of the base platform and defining a plurality of cooling air flow channels. In an embodiment, the plurality of heat transfer fins may be disposed in parallel spaced relationship at a uniform spacing side-to-side. A fan may be disposed in operative association with the plurality of cooling air flow channels for passing a flow of cooling air through the plurality of cooling air flow channels in convective heat exchange relationship with the plurality of heat transfer fins. The ratio of the fin spacing to a thickness of a base portion of each fin of the plurality of heat transfer fins may be in the range from 2 to 3 inclusive. In an embodiment, the plurality of heat transfer fins may comprise flat plate fins having a uniform thickness. In an embodiment, the plurality of heat transfer fins may comprise a plurality of tapered fins, each tapered fin having a base portion and a tip portion with the base portion having a thickness greater then a thickness of the tip portion. The tapered fins may have the fin slope as measured from the fin centerline in the range from 1.0 to 1.5 degrees.

### BRIEF DESCRIPTION OF THE DRAWINGS

For a further understanding of the disclosure, reference will be made to the following detailed description which is to be read in connection with the accompanying drawing, where:

FIG. 1 is a perspective view of an exemplary embodiment of a hest sink device as disclosed herein;

FIG. 2 is a cross-sectional elevation view of the exemplary embodiment of the heat sink device depicted in FIG. 1 taken along line 2-2 of FIG. 1;

FIG. 3 is a cross-sectional elevation view of another exemplary embodiment of the heat sink device disclosed herein showing a different configuration of heat transfer fins;

FIG. 4 is a plan view of the heat sink device depicted in FIG. 2 taken along line 4-4 of FIG. 2;

FIG. 5 is a perspective view of the heat sink device as disclosed herein housed in a cooling air duct;

FIG. 6 is a cross-sectional elevation view taken along line 6-6 of FIG. 5;

FIGS. 7A and 7B are side elevation views showing various dimensional parameters with respect to a uniform thickness heat transfer fin and a tapered heat transfer fin, respectively; and

FIGS. 8A, 8B, 8C and 8D are side elevation views showing various dimensional parameters with respect to fins, respectively, having bumps/risers, having fin cut-offs, having a wave-like configuration, and having an arcuate configuration.

### DETAILED DESCRIPTION OF THE INVENTION

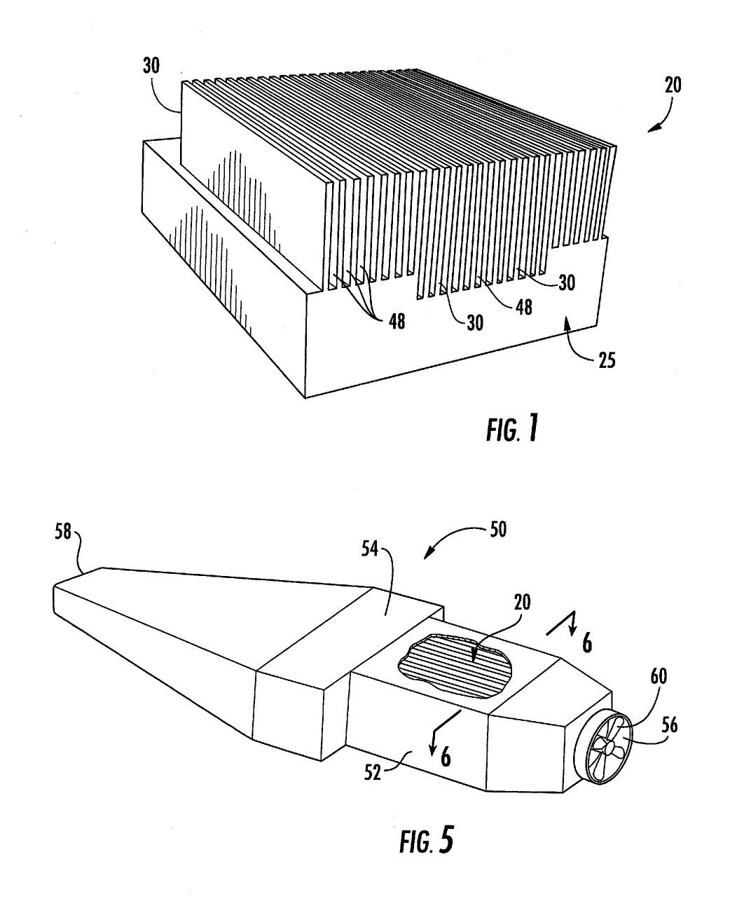

Referring initially to FIGS. 1 - 4, there are depicted exemplary embodiments of a heat sink device 20 for cooling electronics components, for example isolated-gate bipolar transistors, semiconductor devices, capacitors and other electronics components that generate heat during operation. The heat sink device 20 will be described herein in application for cooling a power electronics module 22 of a variable frequency drive. In the depicted embodiments, the power electronics module 22 includes an isolated-gate bipolar transistor (IGBT) 24 and may include other semiconductor devices (not shown), capacitors (not shown), or other heat generating components. Variable speed drives are used, for example, in connection with variable speed drive motors (not shown) for driving refrigerant vapor compressors, air moving devices and/or water pumps on refrigerant vapor compression systems of transport refrigeration units for controlling a temperature within the cargo box of a refrigerated container for shipping perishable cargo by sea, by road, by rail or intermodally.

The heat sink device 20 includes a base platform 26, a plurality of upright members 28, and a plurality of heat transfer fins 30. The base platform 26, the upright members 28 and the heat transfer fins 30 may be formed by extrusion, by casting, or by machining to form an integral one-piece heat sink device 20. The heat sink device 20 may be formed of aluminum, aluminum alloys, copper, copper alloys, or other materials having a high thermal conductivity.

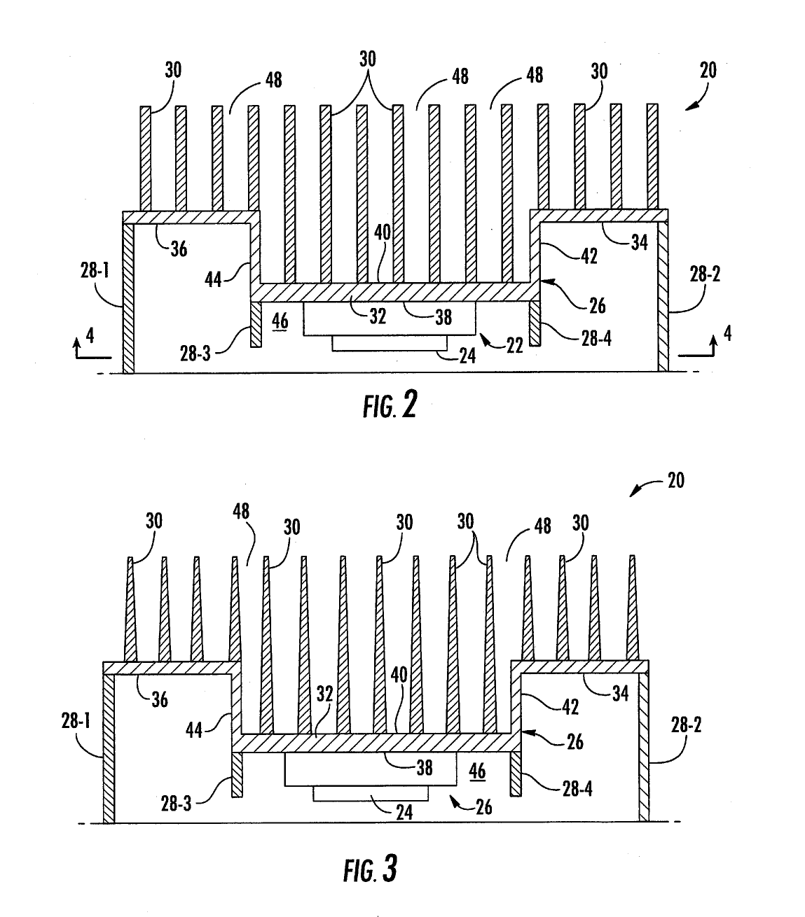

In the depicted embodiment, the base platform 26 has a middle span 32, a right-hand span 34 (to the right of the middle span 32 as viewed in FIGS. 2 and 3) and a left hand span 36 (to the left of the middle span 32 as viewed in FIGS. 2 and 3). Link member 42 connects the right-hand span 34 of the base platform 26 to the right end of the middle span 32 and link member 44 connects the left-hand span 36 of the base platform 26 to the left end of the middle span 36. In the depicted embodiments, the link member 42 extends perpendicularly to the right-hand span 34 and to the middle span 32 and the link member 44 extends perpendicularly to the left-hand span 36 and to the middle span 32. It is to be understood, however, that the base platform 26 may take other forms, including a flat plate, a plate having one or more recessed spans, a plate having one or more raised sections, a plate having a combination of one or more recessed spans and one or more raised sections.

The base platform 26 has a first surface 38 on one side thereof and a second surface 40 on the opposite side thereof. Upright members 28-1, 28-2, 28-3, 28-4 extend outwardly from the first surface 38 of the base platform 26, which in the embodiments depicted in FIGS. 2- 4 is on the lower side of the base platform 26. A cavity 46 is defined on the lower side of the base platform 26 bounded by the wall 25 formed by the outboard upright members 28-1 and 28-2 and the laterally extending upright members interconnecting members 28-1 and 28-3. The power electronics module 22 is housed within the cavity 46. In the depicted embodiment, the IGBT 24 is mounted in a central portion of the cavity 46 between the inboard uprights 2-3 and 28-4 and disposed in conductive heat transfer relationship with the middle span 32 of the base platform 26. Although not shown, it is to be understood that other heat generating components of the power electronics module may be disposed in the two side portions of the cavity 46 in conduction heat transfer relationship with the respective right-hand and left-hand spans 34, 36 of the base platform 26. Further, it is to be understood that the configuration of cavity 46 and the arrangement and type of the power electronics housed therein is exemplary and other arrangements are permissible.

Heat transfer fins 30 extend outwardly from the second surface 40 of the base platform 26, which in the embodiments depicted in FIGS. 1-3 is on the upper side of the base platform 26. The plurality of heat transfer fins 30 extending outwardly from the base platform 26 of the heat sink device 20 may be arrayed in laterally spaced, parallel relationship and extend generally longitudinally along the second surface 40 of the base platform 26 to form a plurality of cooling air flow channels 48, including a cooling air flow channel 48 between each of the various sets of neighboring heat transfer fins 30. As will be discussed further hereinafter, a flow of cooling air may be passed through the channels 48 in heat exchange relationship with the heat transfer fins 30 to remove heat from the heat transfer fins 30. As the heat transfer fins 30 are disposed in conductive heat transfer relationship through the base platform 26 of the heat sink device 20 with the cavity 36 and the power electronics module 22 housed therein, heat generated by the power electronics module 22 is effectively transferred to and removed by the cooling air flow passing through the channels 48 without the cooling air flow directly contacting the power electronics module 22 housed within cavity 46.

In the embodiment depicted in FIG. 2, the heat transfer fins 30 comprise flat plate fins having a rectangular cross section profile of uniform thickness from base to tip. In the embodiment depicted in FIG. 3, the heat transfer fins 30 comprise flat plate fins having a tapered cross section profile of tapering thickness, being tapered inwardly from base to tip. In the uniform thickness embodiment for example, the heat transfer fins 30 may have a thickness in the range of from 3 to 4 millimeters (0.12 to 0.157 inches) and spaced side-to-side at spacing in the range of 10 to 11 millimeters (0.39 to 0.43 inches). In the uniform thickness embodiment, the base platform 26, the upright members 28 and heat transfer fins 30 may be formed by extrusion as an integral, one-piece heat sink device 20. In the tapered fin embodiment for example, the heat transfer fins may have a thickness at the fin base in the range of 3 to 4 millimeters (0.12 to 0.157 inches) and inwardly sloping sides having a slope greater than 1 degree and less than 1.5 degrees. In the tapered thickness fin embodiment, the base platform 26, the upright members 28 and heat transfer fins 30 may be formed by casting as an integral, one-piece heat sink device 20. Further, the fin density and fin parameters, such as cross-section thickness, height and form factor, may be selectively varied along the base platform 26 to provide the most optimal heat exchange pattern and temperature distribution across the longitudinal and lateral expanse of the base platform 26 to maintain the power electronics housed within the cavity 46 below the desired operational threshold temperature. For instance, higher fin density and increased cross-section thickness may be desired in the area surrounding the higher power generation electronics.

It is to be understood that in other embodiments, the heat transfer fins 40 may be curved plate fins or wave-like fins extending longitudinally in parallel spaced relationship. The heat transfer fins 30 may have a cross-section form that is rectangular or tapered, as shown in the depicted embodiments, but may instead have a cross-section form that is triangular, trapezoidal, hyperbolic, parabolic, elliptical or other desired cross-section shape. The heat transfer fins 30 may include heat transfer enhancements such as, but not limited to surface roughness, beads, surface bumps or risers, louvers, off-sets, and cut-offs between fins. Any combination of the abovementioned heat transfer enhancement features may be used on the heat sink device 20 disclosed herein.

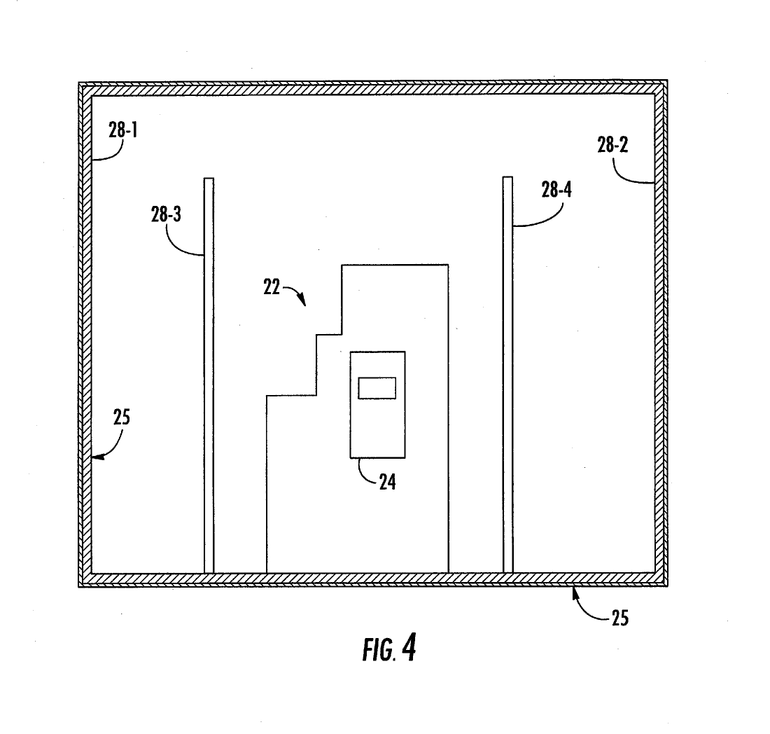

Referring now to FIGS. 5 and 6, the heat sink device 20 is shown disposed within a housing 50 defining a chamber 52 wherein the heat sink device 20 is disposed and also defining a cooling air flow duct 54. The housing 50 further includes a cooling air inlet opening 56 at a first end of the housing 50 and a cooling air outlet opening 58 at a second end of the housing 32 longitudinally opposite the first end of the housing 50. A cooling air fan 60 is provided in operative association with the housing 50 for passing cooling air through the flow duct 54. The cooling air fan 60 may be mounted in the cooling air inlet opening 56 for blowing cooling air through the flow duct 54 or may be mounted in the cooling air outlet opening 42 for drawing cooling air through the flow duct 54. In either arrangement, the cooling air fan 50 is operative to pass a flow of cooling air, typically, but not limited to, ambient air, through the channels 48 formed between the various sets of neighboring pairs of heat transfer fins 30.

When disposed within the housing 50, the tips of the heat transfer fins 30 are juxtaposed in substantially abutting relationship with one interior wall of the housing 50, while the end faces of the upright members forming the bounding wall 25 are juxtaposed in substantially abutting relationship with the opposite interior wall of the housing 50. The cooling air flow passes through the channels 48 across and over, and in convective heat exchange relationship with, the heat transfer surface of the heat transfer fins 30. In this manner, heat generated by the power electronics module 22 housed in the chamber 46 is removed by the cooling air flow by means of conductive heat exchange from the cavity 46 and the power electronics module 22 through the base platform 26 to the heat transfer fins 30 and by means of convective heat exchange from the heat transfer fins 30 to the cooling air flow passing through the channels 48. However, the power electronics module 22, being disposed in the cavity 46, remains isolated from the cooling air flow and therefore not exposed to moisture or corrosive elements that might be present in the cooling air flow.

In the depicted embodiment, the cooling air fan 60 is mounted in the cooling air inlet opening 56 and operates to blow ambient air into and through the cooling air flow duct 54 to pass across and over the surfaces of the heat transfer fins 30 and the base platform 26 of the heat sink device 20. To achieve sufficient convective heat transfer between the cooling air flow and the heat transfer fins 30 and the base platform 26 of the heat sink device 20 to ensure cooling of the power electronics module 24 to a temperature below a threshold temperature of 85° C. (185° F.) in accord with the method disclosed herein, the cooling air flow may be passed through the flow channel at an air flow velocity in the range of from 4 to 20 millimeters per second per Watt of heat rejection by the power electronics module 24.

By way of example, tests of a prototype of the heat sink device 20 housing a 300 Watt IGBT and disposed in a cooling air flow duct at or within a distance of one-half the width of the heat sink device downstream of the outlet of the cooling air fan 60. Additionally, the heat transfer fins 30 were tapered fins having a height of 45 millimeters (1.77 inches), a base width of 3 millimeters (0.118 inches) and a tip width of 1.43 millimeters (0.056 inches) on the right-hand and left-hand sections 34, 36 of the base platform 26 and having a height of 70 millimeters (2.76 inches), a base width of 4 millimeters (0.157 inches) and a tip width of 0.56 millimeters (0.022 inches) on the middle section 32 of the base platform 26. The base platform 26 of the tested heat sink device 20 had a thickness of 8 millimeters (0.315 inches) in the middle section 32 and a thickness of 4 millimeters (0.157 inches) in each of the right-hand side and left-hand side sections 34, 36 of the base platform 26. The heat sink device was cast as an integral one-piece heat sink device 20 using an AlSi12 aluminum silicon alloy. The temperature of the 300 W IGBT was maintained below a threshold maximum temperature of 85° C. (185° F.) using a cooling air flow having at inlet temperature of 39° C. (100° F.) passing through the cooling air flow channels at an air flow velocity of in the range of at least 3.0 meters/second (9.8 feet per second) to 8.0 meters per second (26 feet per second) at a fan output cooling air flow rate in the range from 70 to 90 CFM (cubic feet per minute) (2.0 to 2.5 cubic meters per minute).

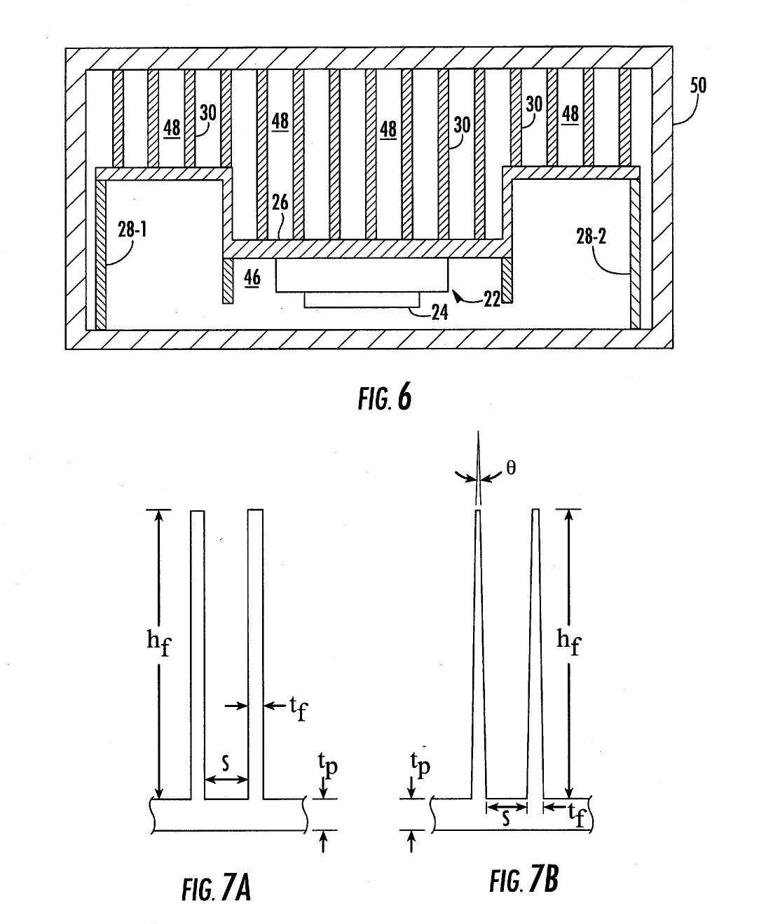

Various specific non-dimensional geometric ratios have been identified and quantified for facilitating manufacturing and enhancing heat transfer performance of the heat sink device 20 disclosed herein, while achieving a reduction in footprint area, a reduction in material content, and a reduction in cost. The various dimensional parameters referred to in the following paragraphs are shown in FIG. 7A with respect to a heat transfer fin having uniform thickness and in FIG. 7B with respect to a tapered heat transfer fin.

The ratio of the height of the heat transfer fins 30 to the thickness of the base platform 26 from which the fins 30 extend should lie in the range of 2 to 30, inclusive, to facilitate manufacturing.

The ratio of the thickness tₚ of the base platform 26 from which the fins 30 extend to the nominal fin thickness, which for a fin having a uniform thickness t_{f} and for a fin having a non-uniform thickness is an average thickness (t_{b}−tₜ)/2, should be in the range from 0.5 to 1.0, inclusive, to ensure adequate conductive heat transfer between the fins 30 and the base platform 26.

For tapered fins, the ratio of the difference between the thickness of the fin base and the thickness of the fin tip (t_{b}−tₜ) to the fin height h_{f} should be such as to provide a fin slope Ø, as measured from the fin centerline, in the range from 1.0 to 1.5 degrees, inclusive, to facilitate casting of the heat sink device 20.

The ratio of the spacing S between the side walls of neighboring fins 30 at the base of the fins to the thickness of the fins t_{b} at the fin base should be in the range from 2 to 3, inclusive, to facilitate manufacturing.

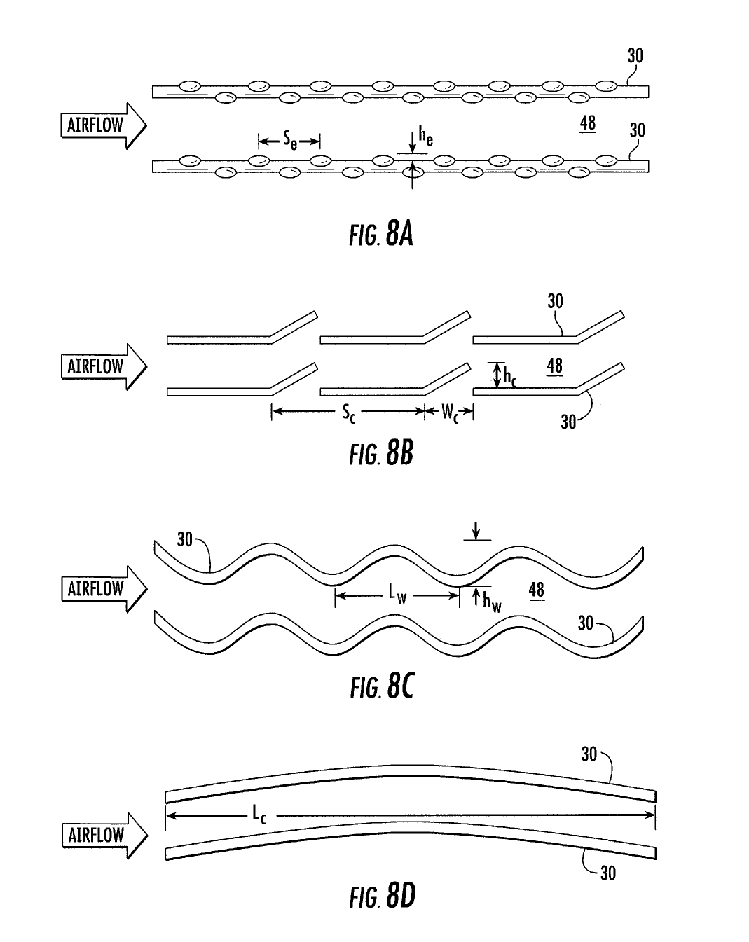

As noted previously, the heat transfer fins 30 may include heat transfer enhancements such as surface roughness, surface bumps, which includes risers, and fin cutoffs. With respect to surface roughness, the surface roughness enhancement may have a height in the range of 0.38 to 1.52 millimeters (0.015 to 0.06 inches). With respect to fins 30 having surface bumps or risers, see FIG. 8A, the ratio of enhancement height hₑ to enhancement spacing Sₑ may have a value in the range of 0.01 to 0.10 and more narrowly in the range of 0.02 to 0.05. With respect to fins 30 having fin cutoffs, see FIG. 8B, the ratio of the cutoff width w_{c} to the spacing S_{c} between cutoffs may have a value in the range of 0.25 to 0.75, and more narrowly in the range of 0.4 to 0.6, and the ratio of the cutoff height h_{c} to fin spacing may have a value in the range of 0.1 to 0.5.

For wave-like heat transfer fins, see FIG. 8C, the ratio of wave height h_{w} to wave length l_{w} may have a value in the range of 0.06 to 0.56, and more narrowly in the range of 0.12 to 0.28. The heat transfer fins may be arcuate in longitudinal expanse having a nominal curvature radius and a curvature length. For example, in an embodiment, the arcuate fins may have a curvature that has an upwardly convex profile in the vertical so that water/condensate would drain off rather than collect in the curve of the arcuate fin. For such a curved fin, see FIG. 8D, the ratio of the nominal curvature radius of the fin to the channel length L_{c} of the fin may have a value in the range of 0.5 to 3, and more narrowly in the range of 0.8 to 1.5.

With the heat sink device 20 as disclosed herein, heat may be removed from the cavity 36 and the power electronics module 24 disclosed within the cavity 36 through primarily conductive heat exchange to the base platform 26 and therethrough to the heat transfer fins 30 and thence by primary convective heat exchange trough the heat transfer fins 30 to the cooling air flow passing through the channels 48 of the heat sink device 20. In this manner, the power electronics module 24 may be cooled without being in direct contact with the cooling air. Thus, the power electronics module 24 will not be exposed to moisture or corrosive elements within the cooling air, typically ambient air, and the potential corrosive effects attendant with such exposure.

The terminology used herein is for the purpose of description, not limitation. Specific structural and functional details disclosed herein are not to be interpreted as limiting, but merely as basis for teaching one skilled in the art to employ the present invention. Those skilled in the art will also recognize the equivalents that may be substituted for elements described with reference to the exemplary embodiments disclosed herein without departing from the scope of the present invention.

While the present invention has been particularly shown and described with reference to the exemplary embodiments as illustrated in the drawing, it will be recognized by those skilled in the art that various modifications may be made without departing from the spirit and scope of the invention. Therefore, it is intended that the present disclosure not be limited to the particular embodiment(s) disclosed as, but that the disclosure will include all embodiments falling within the scope of the appended claims.

We claim:

1. A heat sink device for cooling a power electronics module comprising:
a base platform having a first surface and a second surface on opposite sides of the base platform;
a plurality of upright members extending outwardly from the first surface of the base platform and defining a cavity wherein the power electronics module is disposed in conductive heat exchange relationship with the first surface of the base platform;
a plurality of heat transfer fins extending outwardly from the second surface of the base platform and defining a plurality of cooling air flow channels.

2. The heat sink device as recited in claim 1 further including a fan disposed in operative association with the plurality of cooling air flow channels for passing a cooling air flow through the plurality of cooling air flow channels in convective heat exchange relationship with the plurality of heat transfer fins.

3. The heat sink device as recited in claim 1 wherein the plurality of heat transfer fins are disposed in parallel spaced relationship at a uniform spacing side-to-side.

4. The heat sink device as recited in claim 3 wherein the ratio of the fin spacing to a thickness of a base portion of each fin of the plurality of heat transfer fins is in the range from 2 to 3 inclusive.

5. The heat sink device as recited in claim 1 wherein the plurality of heat transfer fins comprise flat plate fins having a uniform thickness.

6. The heat sink assembly as recited in claim 1 wherein the plurality of heat transfer fins comprise a plurality of tapered fins, each tapered fin a base portion and a tip portion, the base portion having a thickness greater then a thickness of the tip portion.

7. The heat sink device as recited in claim 6 wherein the fin slope as measured from the fin centerline is in the range from 1.0 to 1.5 degrees.

8. The heat sink device as recited in claim 1 wherein the base platform has a right span, a middle span and a left span, the right span and the left span being connected to the opposite respective ends of the middle span.

9. The heat sink device as recited in claim 8 wherein the middle span of the base platform has a first thickness, the right span has a second thickness and the left span has a third thickness.

10. The heat sink device as recited in claim 9 wherein each fin of the plurality of fins has a fin base at the base platform having at thickness and the ratio of the base thickness of each fin to the thickness of the respective span of the base platform from which the fin extends is in the range of 0.5 to 1.0 inclusive.

11. The heat sink device as recited in claim 9 wherein each fin of the plurality of fins has a fin height and the ratio of the fin height to the thickness of the respective span of the base platform from which the fin extends in the range of 2 to 30 inclusive.

12. The heat sink device as recited in claim 9 wherein the first thickness of the middle span is in the range of 8 to 10 millimeters and each of the second thickness of right span and the third thickness of the left span is the range of 4 to 8 millimeters.

13. The heat sink device as recited in claim 1 wherein the heat transfer fins are disposed at a non-uniform fin density.

14. The heat sink device as recited in claim 1 wherein each of the plurality of fins has a cross-section profile selected from the group of cross-section profiles including rectangular, tapered, triangular, trapezoidal, hyperbolic, parabolic and elliptical.

15. The heat sink device as recited in claim 1 wherein the plurality of fins comprises wave-like plate fins, each wave-like plate fin having a wave height and a wave length, and a ratio of the wave height to wave length having a value in the range of 0.3 to 0.8.

16. The heat sink device as recited in claim 1 wherein the plurality of fins comprises at least one fin having a heat transfer enhancement in the form of a plurality of surface roughness enhancements having an enhancement height up to 0.060 inches.

17. The heat sink device as recited in claim 1 wherein the plurality of fins comprises at least one fin having a heat transfer enhancement in the form of a plurality of raised bumps having an enhancement height and disposed in spaced relation on a fin heat exchange surface at an enhancement spacing, a ratio of the enhancement height to the enhancement spacing having a value in the range of 0.01 to 0.10.

18. The heat sink device as recited in claim 1 wherein the plurality of fins comprises a plurality of fins having at least one fin cutoff, the fin cutoff having a ratio of a cutoff width to a cutoff spacing in the range of 0.25 to 0.75 and a ratio of a cutoff height to a cutoff spacing in the range of 0.1 to 0.5.

19. The heat sink device as recited in claim 1 wherein the plurality of fins comprises a plurality of arcuate fins having an upwardly convex curvature in a vertical plane.

20. The hat sink device as recited in claim 19 wherein the plurality of arcuate fins have a curvature having a nominal curvature radius and a curvature length, a ratio of the nominal curvature radius to the curvature length having a value in the range of 0.5 to 3.0.

21. The heat sink device as recited in claim 1 wherein the plurality of heat transfer fins comprises fins of at least two different heights.

22. The heat sink device as recited in claim 1 wherein the plurality of heat transfer fins comprises fins of at least two different cross-sections.
